(19) United States
(12) Patent Application Publication
(10) Pub. No.: US 2012/0282552 A1
(43) Pub. Date: Nov. 8, 2012

(54) METHOD FOR OFFSET IMAGING

(76) Inventors: Eynat Matzner, Adi (IL); Israel Schuster, Kiriyat Tivon (IL); Moshe Nakash, Ramat Hashron (IL)

(21) Appl. No.: 13/100,428

(22) Filed: May 4, 2011

(51) Int. Cl. G03F 7/20

(52) U.S. Cl. 430/300; 430/320

(57) ABSTRACT

A method for writing an image to a surface of an offset media (100) includes mounting the offset media on the imaging drum (204); imaging on a first part of the surface with high energy radiation to ablate the first part wherein the first part represent non-image data; and imaging a second part of the surface with low energy radiation to fixate image data on the second part.

### CROSS REFERENCE TO RELATED APPLICATIONS

Reference is made to commonly-assigned copending U.S. patent application Ser. No. (Attorney Docket No. K000240US01/NAB), filed herewith, entitled OFFSET IMAGING SYSTEM, by Matzner et al.; the disclosure of which is incorporated herein.

### FIELD OF THE INVENTION

This present invention relates to an imaging system for a computer-to-plate (CTP) printing system and more specifically to a processless system which includes a dedicated imaging head in conjunction with an offset printing plate.

### BACKGROUND OF THE INVENTION

Most of the known processes of making offset printing plates require the use of chemicals to dissolve the non-image area of the plate. Other processes such as pre-wash, pre-heat, gumming, and post-baking may also be used. All these processes are costly and may not be environmentally friendly.

Normal plates are divided into two categories, negative plates where the exposure is done in the image area causing the coating in the image to be stronger, and positive plates in which the exposure to the laser is done on the non-image area that is weakened by the energy.

In negative plates normally a stronger and more robust image is achieved due to chemical cross linking, and the weak non-image area is dissolved by a developer and washed off. In positive plates the image is generally less robust but after exposure, the non-image is weaker and can selectively be dissolved and removed by a developer. Both positive and negative plates are gummed after the exposure of the aluminum substrate background.

### SUMMARY OF THE INVENTION

Briefly, according to one aspect of the present invention a method for writing an image to a surface of an offset media includes mounting the offset media on the imaging drum; imaging on a first part of the surface with high energy radiation to ablate the first part wherein the first part represent non-image data; and imaging a second part of the surface with low energy radiation to fixate image data on the second part.

These and other objects, features, and advantages of the present invention will become apparent to those skilled in the art upon a reading of the following detailed description when taken in conjunction with the drawings wherein there is shown and described an illustrative embodiment of the invention.

### BRIEF DESCRIPTION OF THE DRAWINGS

FIG. 1 is a schematic representation of a plate consisting of hydrophilic and hydrophobic layers;

FIG. 2 is a schematic representation of a plate imaging device; and

FIG. 3 is a schematic representation of printing sleeves mounted on a printing cylinder.

### DETAILED DESCRIPTION OF THE INVENTION

In the following detailed description, numerous specific details are set forth in order to provide a thorough understanding of the disclosure. However, it will be understood by those skilled in the art that the teachings of the present disclosure may be practiced without these specific details. In other instances, well-known methods, procedures, components and circuits have not been described in detail so as not to obscure the teachings of the present disclosure.

While the present invention is described in connection with one of the embodiments, it will be understood that it is not intended to limit the invention to this embodiment. On the contrary, it is intended to cover alternatives, modifications, and equivalents as covered by the appended claims.

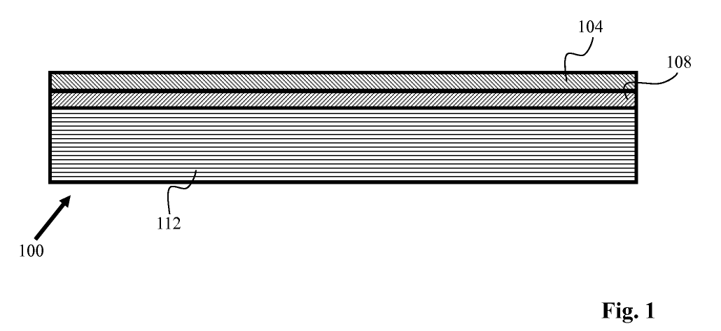

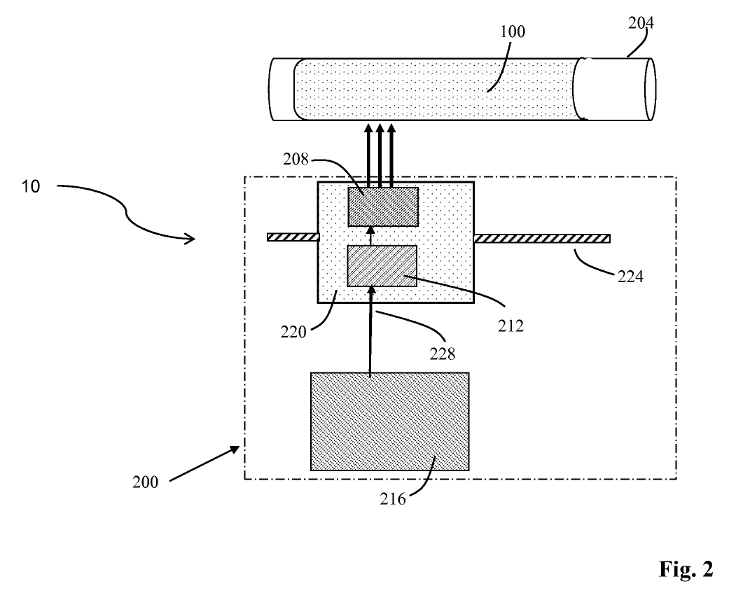

The plate imaging system 10, shown in FIG. 2 provides a processless solution for making offset printing plates or sleeves. The system includes two main components. The first component is an offset plate 100, shown in FIG. 1. Offset plate 100 is neither a negative and nor a positive plate. Offset plate 100 is configured for exposure by laser means over the entire offset plate 100 surface.

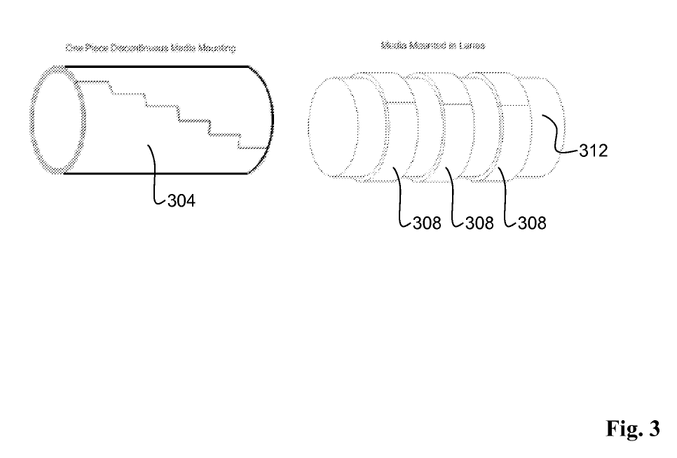

Offset plate 100 is based on a two layer construction, a bottom hydrophilic layer 108 and a top hydrophobic layer 104. The hydrophilic layer allows the elimination of the gumming step. The two layers 104 and 108 are positioned on a support layer 112. Similarly a printing sleeve 304 (FIG. 3) having a bottom hydrophilic layer 108 and a top hydrophobic layer 104 can be employed according to the invention. FIG. 3 shows a continuous sleeve 304 mounted on a cylinder 312 and several separated sleeve sections 308 mounted on a cylinder.

FIG. 2 shows an imaging device 200. The imaging device 200 includes an imaging carriage 220 on which a laser imaging unit 208 and a laser intensity adjustment element 212 are mounted. The laser imaging unit 208 is configured to offset plate 100, which is mounted on a rotating drum 204. The carriage 220 is adapted to move substantially in parallel to drum 204 guided by an advancement screw 224.

Offset plate 100 is exposed by laser imaging unit 208. Laser imaging unit 208 ablates the hydrophobic layer 104. The ablated parts of hydrophobic layer 104 represent non-image areas on offset plate 100. The non-imaged areas are represented by the image data provided to the laser imaging unit 208 by controller 216. The ablation of hydrophobic layer 104 is achieved by operating laser imaging unit 208 at high power. The operating power of laser imaging unit 208 is controlled by the laser intensity adjustment element 212. The increased power applied on the non-image areas ablates the hydrophobic layer 104. In the image areas, the laser power is reduced by the adjustment element 212 to cause strengthening of the image by cross linking the coating and by imparting adhesion between the plate layers 104 and 108.

The laser imaging unit 208 is used on the entire offset plate 100. The non-imaging parts of the plate are imaged by utilizing higher laser power of imaging unit 208, whereas the imaging parts are imaged by operating imaging unit 208 at a lower laser power. The power of the imaging unit 208 is adjusted according to the image data 228 provided from controller 216, by the adjustment unit 212. This concept provides the benefits of both negative and positive plate technologies. A clean background will be achieved as in positive plates, in addition to the robustness of negative plates.

Since the processes on the plate are thermal in nature, the type and rate of the reaction on the plate is determined by the local temperature. At points where layer removal is required, the laser head may deliver high power laser spot which ablates the hydrophobic layer on the plate. At points where the plate active layer should be fixed, the laser head provides lower energy levels, which induces a fixating reaction.

In summary, this system is different from known CTP systems, in that it exposes every part of the plate, partly by ablation of layer 104 to the level of layer 108 (by using higher laser power) and partly by fixation of layer 104 (by using lower laser power), depending on the imaging data 228.

While the invention has been described with respect to a limited number of embodiments, these should not be construed as limitations on the scope of the invention, but rather as exemplifications of some of the preferred embodiments. Other possible variations, modifications, and applications are also within the scope of the invention. Accordingly, the scope of the invention should not be limited by what has thus far been described, but by the appended claims and their legal equivalents.

### Parts List

10 plate imaging system
100 offset plate (media)
104 hydrophobic layer
108 hydrophilic layer
112 support layer
200 imaging device
204 drum
208 laser imaging unit (head)
212 laser intensity adjustment element (power adjustment element)
216 controller
220 carriage
224 screw
228 imaging data
304 continuous printing sleeve
308 sleeve sections
312 cylinder

1. A method for writing an image to a surface of an offset media comprising:
mounting said offset media on said imaging drum;
imaging on a first part of said surface with high energy radiation to ablate said first part wherein said first part represent non-image data; and
imaging a second part of said surface with low energy radiation to fixate image data on said second part.

2. The method according to claim 1 wherein said offset media is a plate.

3. The method according to claim 1 wherein said offset media is a sleeve.

4. A method for writing an image to a media comprising:
focusing low power radiation on the media to strengthen imaged areas by cross linking.
